(19) United States
(12) Patent Application Publication
(10) Pub. No.: US 2021/0036189 A1
(43) Pub. Date: Feb. 4, 2021

(54) Zn(Ge,Sn)N2 FOR GREEN-AMBER LEDS

(71) Applicant: Alliance for Sustainable Energy, LLC, Golden, CO (US)

(72) Inventors: Adele Clare TAMBOLI, Golden, CO (US); Marshall Brooks TELLEKAMP, JR., Denver, CO (US)

(21) Appl. No.: 16/941,949

(22) Filed: Jul. 29, 2020

Related U.S. Application Data
(60) Provisional application No. 62/879,916, filed on Jul. 29, 2019.

(51) Int. Cl. H01L 33/26; H01L 33/00

(52) U.S. Cl. CPC H01L 33/26; H01L 33/005; H01L 33/002

(57) ABSTRACT

Disclosed herein are methods for making Zn(Ge,Sn)N₂ for green-amber LEDs. Disclosed herein are compositions comprising Zn(Ge,Sn)N₂ useful for green-amber LEDs.

### CROSS-REFERENCE TO RELATED APPLICATIONS

This application claims priority under 35 U.S.C. § 119 to U.S. provisional patent application No. 62/879,916 filed on 29 Jul. 2019, the contents of which are hereby incorporated in their entirety.

### CONTRACTUAL ORIGIN

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

Light emitting diodes (LEDs) offer superior efficiency and lifetime when compared to other light emitting means. Some visible wavelengths such as those wavelengths in the green to amber portion of the visible spectrum of light are difficult to produce efficiently by using LEDs. Currently, InGaN green LEDs are available, but suffer from poor efficiency. The efficiency of these emitters is limited by polarization and material quality related to lattice mismatch and the miscibility gap of InGaN at high In compositions.

### SUMMARY

In an aspect, disclosed herein are methods for making II-IV-N₂ comprising light emitting diodes where II is Zn, Mg or Cd and where IV is Si, Ge or Sn. Zn(Ge,Sn)N₂ for green-amber LEDs.

In an aspect, disclosed herein are compositions comprising Zn(Ge,Sn)N₂ useful for green-amber LEDs.

In an aspect, disclosed herein are photon emitting and electroluminescent devices that include the polycrystalline alloy thin films made by the methods disclosed herein.

In another aspect, disclosed herein is a light emitting diode (LED) comprising at least a layer of a group II-group IV-N₂ semiconductor alloy. In an embodiment, the group II element is selected from the group consisting of Zn, Mg or Cd. In an embodiment, the group IV element is selected from the group consisting of Si, Ge, or Sn. In an embodiment, the LED is capable of emitting light at a wavelength of less than 400 nm. In an embodiment, the LED is capable of emitting light at a wavelength of greater than 700 nm. In an embodiment, the LED is capable of emitting light at a wavelength from about 400 nm to about 700 nm. In an embodiment, the LED is capable of emitting light at a wavelength from about 530 nm to about 590 nm. In an embodiment, the LED iscapable of emitting light at a wavelength from about 530 nm to about 550 nm. In an embodiment, the LED comprises ZnGeₓSn₁₋ₓN₂. In an embodiment, the wavelength of emitted light from the LED changes as the value of x varies from 0 to 1. In an embodiment, the wavelength of emitted light changes as the amount of cation disorder in the ZnGeₓSn₁₋ₓN₂ layer changes. In an embodiment, the LED exhibits a luminous efficacy of up to 325 lm/W. In an embodiment, the ZnGeₓSn₁₋ₓN₂ layer is lattice matched within two percent to at least one GaN layer. In an embodiment, the ZnGeₓSn₁₋ₓN₂ layer is lattice matched within two percent to at least one InGaN layer. In an embodiment, the LED has GaN/ZnGeₓSn₁₋ₓN₂/GaN device architecture.

In an aspect, disclosed herein is a method of making a LED comprising at least a layer of a group II-group IV-N₂ semiconductor alloy wherein the method uses MOVCD, HYPE, ALD, or PLD. In an embodiment, the LED further comprises a substrate upon which the at least a layer of a group II-group IV-N₂ semiconductor alloy is grown upon. In an embodiment, the substrate is Al₂O₃. In an embodiment, the substrate is GaN. In an embodiment, the substrate is AlN.

Other objects, advantages, and novel features of the present invention will become apparent from the following detailed description of the invention when considered in conjunction with the accompanying drawings.

### DESCRIPTION OF THE DRAWINGS

FIG. 1 depicts a band gap vs lattice constant plot for II-IV-N₂ emitters exhibiting increased LED wavelength tunability. FIG. 1 depicts highly tunable II-IV-N₂ emitters using traditional alloying—as depicted herein, Group II and IV cation disorder tunes the band gap.

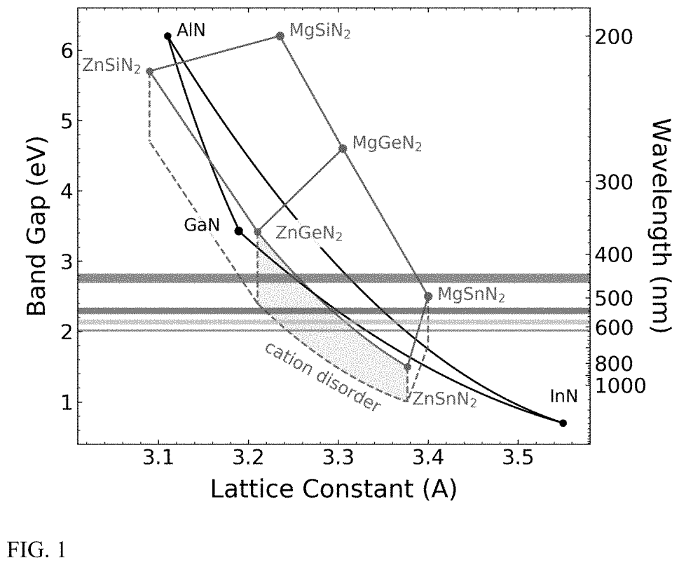

FIG. 2 depicts exemplary crystal structure of cation ordered and cation disordered II-IV-N₂ materials.

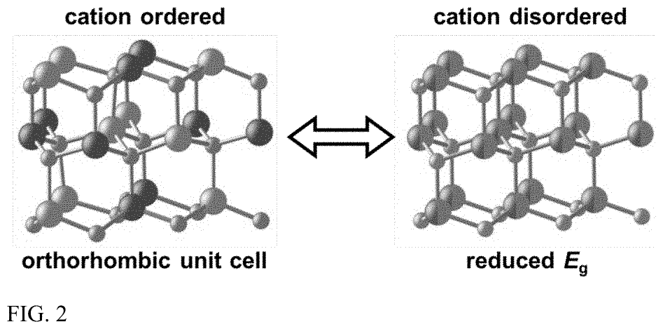

FIG. 3 depicts exemplary band offsets of embodiments of the cation ordered and disordered II-IV-N₂ materials disclosed herein. The left portion of FIG. 3 depicts type-I alignment between the III-N layer and the II-IV-N₂ layer: III-N barriers and II-IV-N₂ wells where the II-IV-N₂ is cation ordered or cation disordered. The center portion of FIG. 3 depicts type-II alignment between the III-N layer and the II-IV-N₂ layer: III-N electron wells and II-IV-N₂ hole wells where the II-IV-N₂ is cation-ordered or cation-disordered. In an embodiment, the type-II alignment can be opposite where holes originate from the III-N layer and electrons from the II-IV-N₂ layer. The right portion of FIG. 3 depicts near-equal alignment between III-N layer and II-IV-N₂ layer. III-N or cation ordered II-IV-N₂ barriers with cation disordered II-IV-N₂ wells. In an embodiment, the materials disclosed herein exhibit a type-II band offset which is ideal for polar materials and also blocks carrier overshoot, for example, electron overshoot.

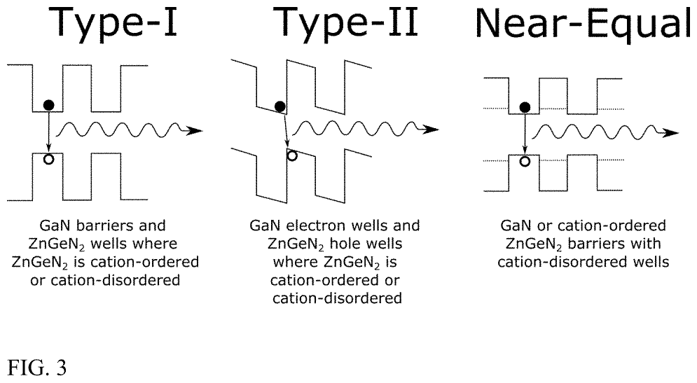

FIG. 4a depicts wavelength numbers using the theoretical values modified from Atchara et. al. Phys. Rev. B (2017) (“Lambrecht” as used herein) of exemplary II-IV-N₂ materials as disclosed herein. FIG. 4a depicts an example of how indium content, when combined with a type-II aligned II-IV-N₂ material, can be used to tune the emission wavelength of an LED. FIG. 4b depicts the effect of Sn alloying and cation disorder on the band gap of the II-IV-N₂, not necessarily the emitted wavelength of a device comprising such a layer. Without being limited by theory, Si alloying would point in the opposite direction of Sn alloying and Mg alloying would point along the blue line to the top right.

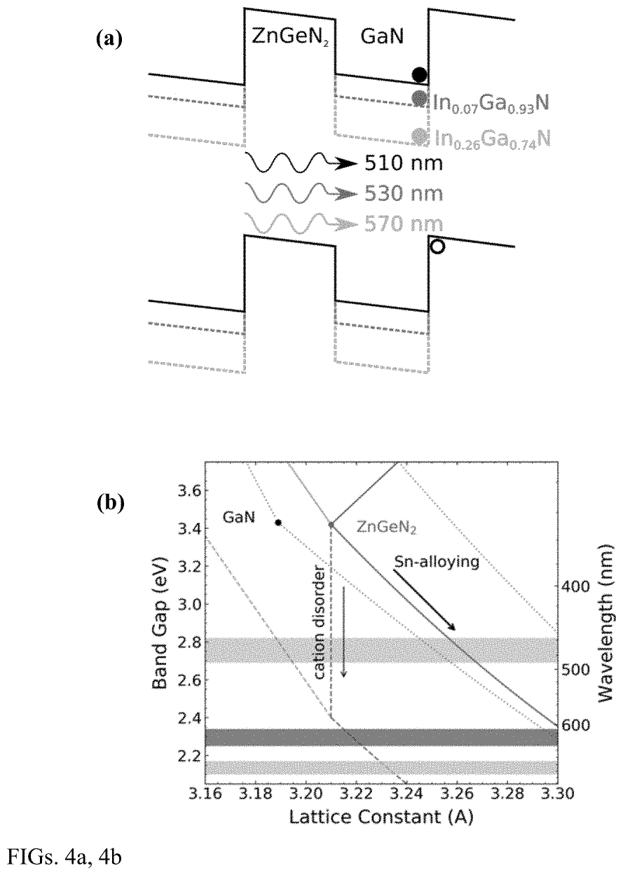

FIG. 5 depicts additional aspects to consider for polarization engineering of II-IV-N₂ materials disclosed herein. Without being limited by theory, local carrier density and electron-hole wavefunction overlap compete and must be optimized. In an embodiment, electron tunnel barriers act as hole wells. In an embodiment, no electron blocking layer (EBL) occurs and, therefore the hole injection is more efficient.

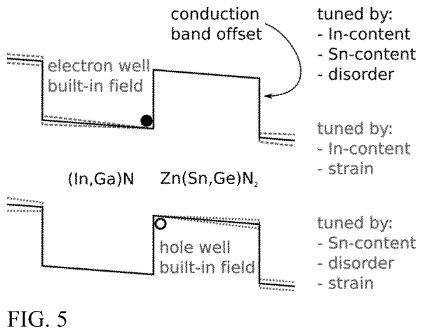

FIG. 6 depicts a reciprocal space map around the GaN and ZnGeN₂ (10-15) reflection indicating in-plane lattice matching between the ZnGeN₂ quantum well (as depicted here it is 5 repetitions of 2.6 nm ZnGeN₂ wells with 10 nm GaN barriers) and the GaN underlayer.

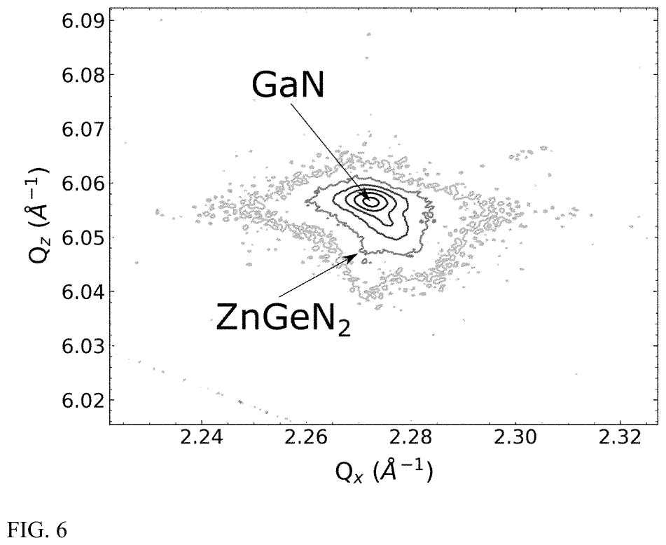

FIG. 7 depicts an X-ray diffraction (XRD) symmetric scan of a 20 nm QW within GaN cladding. This diffractogram shows the GaN (0002) reflection, the ZnGeN₂ (0002) reflection (disordered wurtzite indicies), and pendellosung thickness fringes arising from the uniform vertical coherence length within the layers.

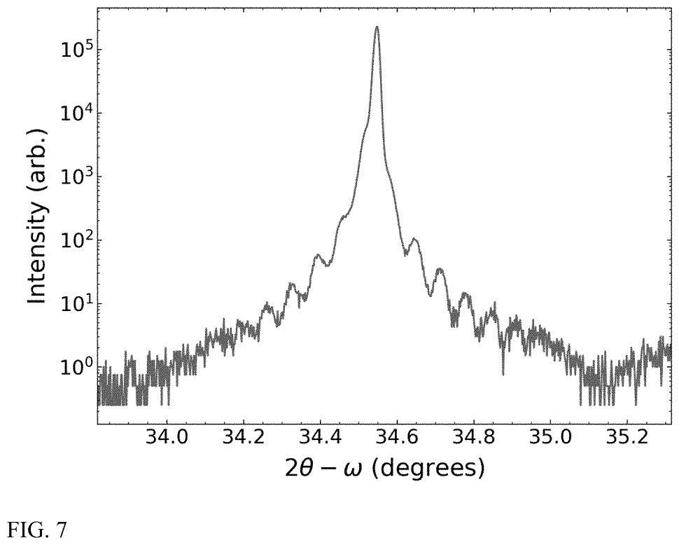

FIG. 8 depicts and compares red, orange and other photoluminescence from a series of GaN/II-IV-N₂/GaN quantum wells.

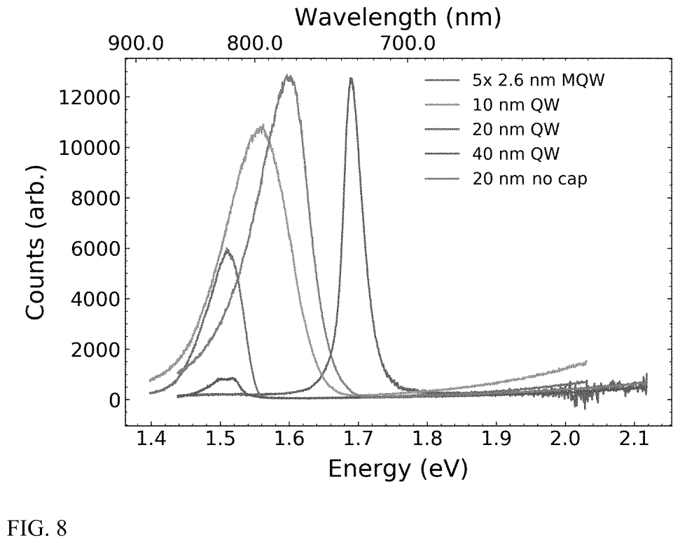

FIG. 9a depicts luminescence data for exemplary disordered materials and compositions disclosed herein including room temperature photoluminescence of disordered ZnGeN₂ on a lattice-mismatched sapphire with a peak at about 480 nm attributed to band edge and wherein FWHM is about 17 nm. Merely presented to provide contrast to FIG. 9a, FIG. 9b depicts photoluminescence of a ZnGeN₂ ordered material, as modified from K. Du et al. Journal of Crystal Growth 310 (2008), pp 1057-1061.

FIG. 10 depicts energy vs. position of an embodiment of a LED with ZnGeN₂ quantum wells. In this depiction, type-II band alignment is exhibited.

FIG. 11 compares the polarization induced band bending for small percentages of alloyed Sn in the quantum wells as depicted in FIG. 10.

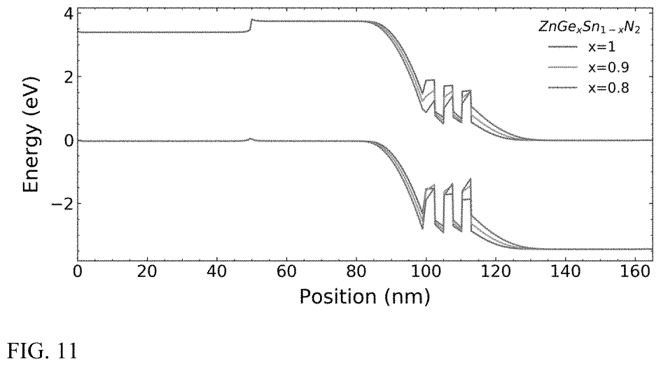

### DETAILED DESCRIPTION

Solid-state lighting (SSL) technologies have the potential to double current luminous efficacies by moving from inefficient phosphor-converted designs to more efficient color-mixed LEDs (cm-LEDs). These cm-LEDs will be the highest efficiency white light generators by avoiding fundamental losses associated with the Stokes shift in phosphor-converted designs. In addition, cm-LEDs offer the potential for on-demand spectral tunability to suit specific application spaces, such as matching mission spectra to biological needs and high-value markets such as retail. However, cm-LED efficiency is currently outpaced by phosphor-converted LEDs (pc-LEDs) due to low efficiency emitters in the green to amber color range (530 nm-590 nm), termed the “green gap.” Increased LED efficiency in the green gap is required to realize cm-LEDs.

GaN/InGaN-based blue LEDs are the most efficient light emitter currently available, however at green relevant In compositions InGaN is inefficient, even though it is the current state-of-the-art. Where InGaN alloys fail to reach desired efficiencies due to the miscibility gap, lattice mismatch, and polarization mismatch, fully miscible Zn(Sn,Ge)N₂ alloys can reach band gaps in the green to amber spectral range with <1% lattice mismatch to GaN, potentially eliminating primary loss mechanisms associated with material quality, polarization, and high-current efficiency loss (droop). Zn(Sn,Ge)N₂ active layers, when combined with GaN barriers, also potentially open up an advantageous type-II (staggered) band alignment, driving electrons and holes together and inherently blocking carrier overflow, a key issue for minimizing high-current efficiency losses known as “droop”.

Closing the green gap will allow LED technology to move on from the fundamentally lossy process of phosphor conversion to full color-mixing, enabling a ˜30% increase in ultimate luminous efficacy (from 255 lm/W to 325 lm/W) and a new design space for dynamically tuned LEDs. The importance of cm-LEDs, which will only be realized by closing the green gap, goes far beyond energy efficiency, with significant impacts on human health, productivity, transportation safety, horticulture, and the environment. Physiological responses to light spectra, both visual and non-visual, can impact human health; for instance, decreasing the blue light content in the morning and evening can reinforce our natural diurnal rhythm. Similar response patterns are known for plants and animals.

Materials made using methods disclosed herein may be characterized by standard techniques including advanced spectroscopy such as MER, XPS/UPS, XRD, photoluminescence (PL) and electroluminescence (EL).

Disclosed herein are methods for making and compositions for LEDs that use II-IV-N₂ materials as active layers (photon emitters). Without being limited by theory, in an embodiment, the II-IV-N₂ materials are in a type-I configuration where both electron and hole are confined in the II-IV-N₂ (cation ordered or disordered). In another embodiment, the II-IV-N₂ materials are in a type II configuration where one carrier comes from the II-IV-N₂ and another comes from the III-N, wherein III=Al, Ga, or In.

In an embodiment, LEDs that integrate II-IV-N₂ materials with III-N materials as disclosed herein are described through the wavelength emitted. In an embodiment, LEDs that integrate II-IV-N₂ materials as disclosed herein have a maximum emission of about 4.5 eV and a minimum emission of about 1 eV.

In an embodiment, disclosed herein are compositions and methods for making LEDs comprising highly efficient direct emitters by using ZnGeN₂-based active layers.

In an embodiment, disclosed herein are II-IV-N₂ green and amber emitters that are nearly (within about 2 percent) lattice matched to GaN. In an embodiment, II-IV-N₂ emitters that are lattice matched to GaN result in reduced defect density, reduced polarization fields, and higher radiative efficiency.

Zn(Sn,Ge)N₂, a III-N derivative with a similar crystal structure, is fully miscible, reaching green and amber wavelengths at <1% lattice mismatch to GaN. This results in improved material quality and reduced polarization mismatch, which can eliminate InGaN-related loss mechanisms.

A parameter enabling green-to-amber wavelengths is the implementation of cation disordered Zn(Sn,Ge)N₂, which can be used to tune the band gap at fixed lattice parameter. Without being bound by theory, understanding band offsets and polarization is required for achieving efficient devices. In an embodiment, Zn(Sn,Ge)N₂-containing devices are disclosed herein and polarization fields, and band offsets with respect to GaN, and the effect of cation disorder are also disclosed. In an embodiment, integrating Zn(Sn,Ge)N₂ into established GaN-based devices by replacing the InGaN quantum well region results in improved LEDs.

In an embodiment, and without being limited by theory, in an energy vs. position chart, and in a type-II junction, the strain in the quantum wells drives the holes in the Zn(Ge,Sn)N₂ layer downward and the electrons in the InGaN barriers upward so they are both spatially confined at the interface, increasing the e-h wave function overlap. In a prophetic example, this type-II quantum well structure would have a transition energy of from about 2 eV (ordered ZGN, band-bowing included) to about 300 eV, not including the quantum confinement term which will raise the transition energy. In a prophetic embodiment, balance wavefunction overlap and carrier density are used to improve droop.

Without being limited by theory, for completely ordered ZnGeN₂, approximately 26% In InGaN (not taking into account strain which will likely bow the bands down—i.e. less In needed) is needed to reach amber wavelengths. Considering group IV alloying and cation disorder, predicting the correct structure becomes much more difficult without a detailed experimental understanding of their effects on band alignment and polarization.

In an embodiment structures incorporating the materials disclosed herein can be optimized through polarization engineering. Type-II alignment means electron and hole wells can be tuned individually. Polarization can be tuned by adjusting the alloy composition and strain built-in field can be optimized to balance local carrier concentration and wavefunction overlap at a specific bias point. Thick quantum wells are a potential mitigation strategy for Auger recombination, however thicker wells may reduce wavefunction overlap.

In an embodiment, materials disclosed herein may be grown by either MBE and MOCVD. In an embodiment, ZnGeN₂ and ZnSiN₂ are grown by MOCVD on Al₂O₃ substrates.

Crystalline stability of ZnGeN₂ was observed at greater than 850° C. during vacuum anneal by RHEED. Disclosed herein are methods to grow a low temperature p-GaN capping layer followed by a high temperature p-GaN layer using standard procedures for InGaN devices.

In an embodiment, compositions disclosed herein may be grown using a multi-chamber CVD growth reactor. In an embodiment, room temperature photoluminescence in GaN/Zn(Sn,Ge)N₂/GaN heterostructures is measured. In an embodiment, band offsets with less than 100 meV uncertainty, provide a device architecture design capable of 530 nm-550 nm emission under electrical injection. In another embodiment, green emission (530 nm-550 nm) from a GaN/Zn(Sn,Ge)N₂/GaN device under electrical injection is contemplated.

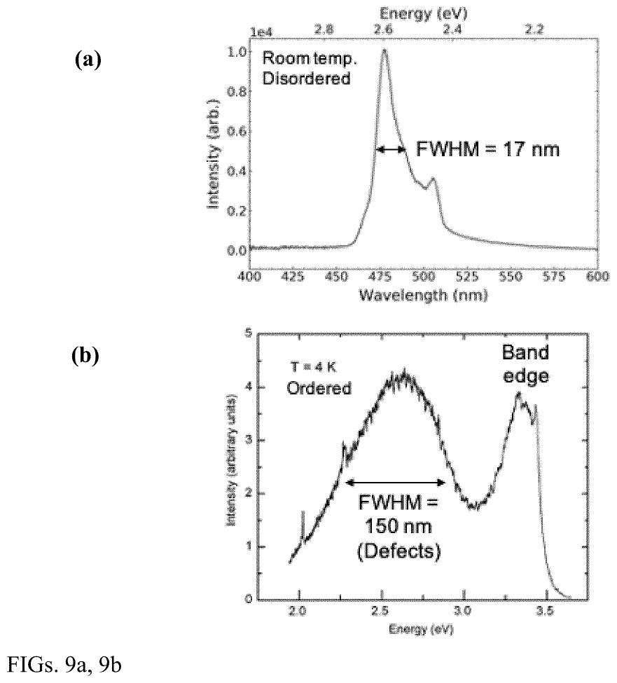

In an embodiment, ZnGeN₂ active layers for GaN-based green and blue-green LED's ZnGeN₂ (ZGN) is lattice-matched to GaN providing a reduction in active layer dislocations. In an embodiment, ZGN order/disorder tunability is demonstrated using methods disclosed herein. Up to 1 eV of tunability (drop) in the band gap can be achieved by introducing disorder. In an embodiment, the 1 eV of tunability can result in emission at 2.4 eV (515 nm). As depicted in FIG. 9a, the 1 eV of tunability results in emission at 2.5-2.6 eV (477 nm-496 nm).

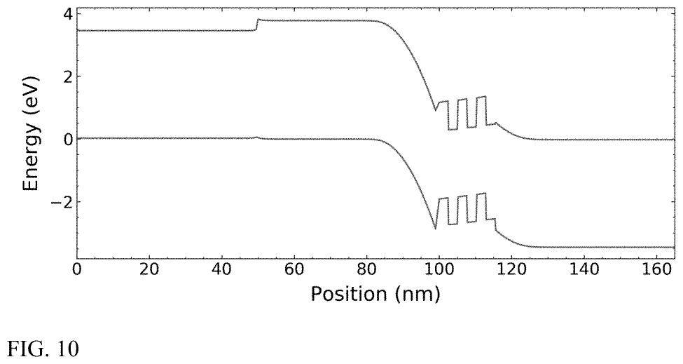

Without being limited by theory, there is a minimal spontaneous or piezoelectric polarization component at a GaN-ZGN interface because they have the about the same lattice constant and spontaneous polarization coefficient of 0.023 C/m² for ZGN, and 0.020 C/m² for GaN (see FIG. 10, for example).

In an embodiment, through the combination of materials and alloying, polarization matching should be possible between GaN and Zn(Ge,Sn)N₂, or for small indium fractions of InGaN. Without being bound by theory, the band can be lowered through alloying Sn on the group IV site, all the way to 1 eV. ZnGeSnN₂ is fully miscible. This is in contrast to InGaN, which is a primary reason for poor crystal quality in InGaN emitters. In an embodiment, Sn increases the lattice, increasing piezoelectric polarization in the same way as In does in InGaN. Without being limited by theory, ZnSnN₂ has a much lower spontaneous polarization than InN, and it is about the same value as GaN of 0.029 C/m² as compared to 0.042 C/m² for InN.

Without being bound by theory, due to the disorder-induced band gap reduction, much less Sn is needed to reach green-relevant band gaps, on the order of 5-15%, compared to 25-30% In for InGaN. In strain-equivalent terms this is about 0.5-1% lattice strain for ZnGeSnN₂ and 2.7-3.7% for InGaN.

Coupled with the lower Psp this indicates the QCSE will be much lower in a GaN/ZnGeSnN₂/GaN (M)QW leading to a greater electron-hole wave function overlap. This is another primary factor leading to low green efficiency in InGaN LEDs.

In an embodiment, Zn(Ge,Sn)N₂ growth and epitaxy is contemplated. Without being bound by theory, the ZnGeN₂ conduction band is about 0.1 to 1 eV larger than that of GaN, leading to a type-II heterojunction. In an embodiment, the type-II offset is about 2.4 eV which allows for green light emission to be engineered through disorder without Sn alloying. In this case, opposite polarization is preferred for e-h wave function overlap, and, in an embodiment, could be strain engineered through small additions of In or Al to the Ga layer, or Sn to the emitter.

In a prophetic embodiment, growth is performed in a MOCVD engineered for use with nitrides II-IV-III₂-N₄ quaternaries. In a prophetic embodiment, it is possible to increase tunability with the addition of dilute amounts of Ga, In, and Al.

The foregoing disclosure has been set forth merely to illustrate the invention and is not intended to be limiting.

We claim:

1. A light emitting diode (LED) comprising at least a layer of a group II-group IV-N₂ semiconductor alloy.

2. The LED of claim 1 wherein the group II element is selected from the group consisting of Zn, Mg or Cd.

3. The LED of claim 1 wherein the group IV element is selected from the group consisting of Si, Ge, or Sn.

4. The LED of claim 1 capable of emitting light at a wavelength of less than 400 nm.

5. The LED of claim 1 capable of emitting light at a wavelength of greater than 700 nm.

6. The LED of claim 1 capable of emitting light at a wavelength from about 400 nm to about 700 nm.

7. The LED of claim 1 capable of emitting light at a wavelength from about 530 nm to about 590 nm.

8. The LED of claim 1 capable of emitting light at a wavelength from about 530 nm to about 550 nm.

9. The LED of claim 1 comprising ZnGeₓSn₁₋ₓN₂.

10. The LED of claim 9 wherein the wavelength of emitted light changes as the value of x varies from 0 to 1.

11. The LED of claim 9 wherein the wavelength of emitted light changes as the amount of cation disorder in the ZnGeₓSn₁₋ₓN₂ layer changes.

12. The LED of claim 1 exhibiting a luminous efficacy of up to 325 lm/W.

13. The LED of claim 9 wherein the ZnGeₓSn₁₋ₓN₂ layer is lattice matched within two percent to at least one GaN layer.

14. The LED of claim 9 wherein the ZnGeₓSn₁₋ₓN₂ layer is lattice matched within two percent to at least one InGaN layer.

15. The LED of claim 13 comprising GaN/ZnGeₓSn₁₋ₓN₂/GaN device architecture.

16. A method of making a LED comprising at least a layer of a group II-group IV-N₂ semiconductor alloy wherein the method uses MOVCD, HVPE, ALD, or PLD.

17. The method of claim 16 wherein the LED further comprises a substrate upon which the at least a layer of a group II-group IV-N₂ semiconductor alloy is grown upon.

18. The method of claim 17 wherein the substrate is Al₂O₃.

19. The method of claim 17 wherein the substrate is GaN.

20. The method of claim 17 wherein the substrate is AlN.
